(19) United States
(12) Patent Application Publication
(10) Pub. No.: US 2005/0059250 A1
(43) Pub. Date: Mar. 17, 2005

(54) Fast etching system and process for organic materials

(76) Inventors: Stephen Edward Savas, San Jose, CA (US); John Zajac, San Jose, CA (US)

Correspondence Address: EDWARD S. WRIGHT, 1100 ALMA STREET, SUITE 207, MENLO PARK, CA, 94025, US

(21) Appl. No.: 10/890,396

(22) Filed: Jul. 13, 2004

Related U.S. Application Data
(63) Continuation-in-part of application No. 09/886,654, filed on Jun. 21, 2001, now Pat. No. 6,838,387.

(51) Int. Cl. H01L 21/311

(52) U.S. Cl. 438/695

(57) ABSTRACT

Plasma reactor and process for very fast etching of organic materials in which a workpiece is placed on a pedestal in a chamber, gas is exhausted from the chamber, an oxidizing gas is introduced into the chamber through a showerhead electrode which is spaced from the pedestal by a distance on the order of 1.0 to 1.5 cm, RF power is applied to the pedestal and/or the showerhead electrode, and pressure within the chamber is maintained at a level on the order of 3 to 15 Torr while an organic material is removed from the workpiece.

### RELATED APPLICATION

This is a continuation-in-part of Ser. No. 09/886,654, filed Jun. 21, 2001.

### BACKGROUND OF THE INVENTION

1. Field of Invention

This invention pertains generally to etching and, more particularly, to a very fast etching system and process for use in the manufacture and backside etching of silicon wafers, integrated circuit packaging, and the manufacture of circuit boards and TFT/LCD displays.

2. Related Art

Historically, reactive ion etching, the prevalent method of plasma-based etching processes for integrated circuit (IC) manufacture, has used radio frequency electrical discharges between substantially parallel electrodes. The discharge produces ions and neutral reactive atoms and molecules that are responsible for the etching action. These etching processes were typically used in IC fabrication for silicon, silicon dioxide, silicon nitride or aluminum removal and used reactant gases containing fluorine or chlorine. Such processes have usually been anisotropic etching processes in which the material to be patterned was removed with the boundary being a plane substantially perpendicular to the wafer surface defined by a photolithographic mask. The typical removal rate of material for these processes was several thousand Angstroms per minute, adequate for the purposes of integrated circuit manufacture. The mask is made of photosensitive material, typically an organic polymer called photoresist. This etching process was called reactive ion etching (RIE) because it was the ions which provided the activation energy for the etching reactions, and the ions usually contained halogen atoms which formed volatile species upon reaction with the exposed material on the wafer.

Under the conditions of the process, the ions from the plasma impact the wafer nearly perpendicular to the wafer surface, thereby activating reactions mostly on surfaces which are substantially parallel to the wafer surface and avoiding etching on surfaces which are perpendicular to the wafer surface.

The etching rate for these processes is adequate for the thin films used in IC fabrication which are usually no more than a few microns thick. It is important that these etching processes not require too much time for completion in order that the cost of the processing not be excessive. Systems for carrying out such processes tend to be relatively expensive. One reason for the high cost and low speed of such systems is that the structures to be etched on wafers are typically somewhat less than one micron in critical lateral dimension and therefore the process must be very clean. Other reasons for the high cost are that the angle of the sidewall produced by the etching must be accurately controlled, as must the transfer of contaminant materials to the surface during the etching process since very minute amounts will destroy the semiconductor's function.

The plasma for RIE is produced by applying radio frequency (RF) power to the pedestal upon which the wafer is placed or to an upper or showerhead electrode above the wafer. In addition to causing electrical breakdown and ionization of the gas, the RF power also produces a DC potential difference between the pedestal and the plasma which accelerates the positive ions to the wafer surface. The ions are thus given sufficient energy to promote the etching processes that are desired. The ions do this by activating the etching reactions of the halogen species with the exposed material on the wafer surface and also causing the reaction products to come off the surface either by sputtering or desorption. See J. W. Coburn and H. F. Winters, Plasma Etching-A Discussion of Mechanisms; Journal of Vacuum Science and Technology, Vol 16, pages 391-403, (1979). Another reason for the effectiveness of this technique is that if impurities which do not form volatile products built up on the surface, the ions from the plasma will sputter them off and thereby allow the etching to continue. Typical ion energies in this type of discharge are of order 100 eV to several hundred eV.

Many types of halogenated gases have been tried in these processes for etching silicon or silicon-based insulators or alloys. In anisotropic etching of silicon, etching should occur only when ion impact promotes the necessary reactions, and the gases currently used for such etching are most commonly chlorine and bromine based gases. Sometimes, however, fluorocarbon gases may be used, but they have a strong tendency to etch the silicon isotropically and undercut the patterning mask.

Isotropic etching of silicon with plasma sources is usually done with fluorocarbons or nitrogen trifluoride as the reactant gases. In the early days of plasma etching, some attempts were also made to etch silicon with sulfur hexafluoride, but it was found to be less efficient than nitrogen trifluoride for isotropic etching. It also had a tendency to leave sulfur-containing residues on the silicon. Etch rates were well below one micron per minute typically with gas pressures of several hundred millitorr and power levels up to several watts per square centimeter. See K. M. Eisele, Journal of the Electrochemical Society, Vol. 128, page 123-126 (1981); W. Beinvogl, H. R. Deppe, R. Stokan and B. Hasler, I.E.E.E. Transactions on Electron Devices, Vol. ED-28, page 1332-1337 (1981); and M. Mieth and A. Barker, Anisotropic Etching of Polysilicon Using SF₆ and CFCl₃, J. Vac. Sci. Technol. A1, 629-635 (1983).

The RIE process, however, has not been found suitable for some etching steps in semiconductor fabrication because of the energy of the ions which impact upon the wafer and the active electrical charging it causes on the surface of the wafer. These include processes where sensitive areas of the mono-crystalline silicon are exposed and subject to dislocations and impaired function due to ion impact. Among such processes are isotropic processes for etching organic contaminants left on the wafer after other patterning processes where no directionality of the etch is desired.

U.S. Pat. 5,198,634 discloses a process for isotropic etching of organic polymers using the parallel plate discharge in which the gas pressure in the process chamber is much higher than in previous work. In that process, the radio frequency power input was also limited in proportion to the pressure and the volume of the plasma (less than 0.15 watts/cm) in order to reduce electrical and ion impact damage to the semiconductor devices located on the wafer surface. This process permits a relatively high rate of removal of organic residues or other undesired material from the surface of a semiconductor wafer while not causing electrostatic charge-based damage to the sensitive transistors being fabricated on the wafer surface. The pressures employed in the process are so high (typically 20-30 Torr) that the ions from the plasma make many collisions in moving to the wafer and only have a few eV of energy remaining when they impact the wafer. However, the process relies on the use of higherwafer temperature (typically higher than 150° C. and usually about 250° C.) to achieve its rate of etching, typically of organic materials. It avoids charging and ion damage while producing high removal rates for the organic photoresist, usually about two microns per minute. It also avoids sputtering the exposed materials of the semiconductor devices or interconnects on the wafer surface. This process, however, is not capable of removing organic materials at high rates when the wafer temperature is low (<1000 Celsius), nor can it achieve rapid etching of silicon or silicon-based materials. At temperatures below 100° Celsius, the etching rate drops by at least an order of magnitude to about a few thousand Angstroms per minute. High rate etching at low temperature requires a larger supply of chemically reactive species, such as oxygen or fluorine atoms, than this process can supply. It also requires an alternative source of activation energy in order to produce the desired etching reactions at the surface of the substrate. In RIE, that energy is substantial and causes sputtering of materials and even crystalline damage to the silicon of the wafer. In other applications, such ion bombardment will cause sputtering of some of the materials exposed on the workpiece and problems in the finished product.

In applications where crystalline silicon is to be etched isotropically at high rates, there have been reports of such processes succeeding without benefit of ion bombardment, but these have used very high density plasma torches in which the gaseous species, particularly fluorine atoms, are at high temperatures. In such plasmas, the heat transfer to the wafer by the gas is very considerable, and the plasma is generally scanned across the substrate at a very high speed in order to avoid heat damage. See S. Savastiouk, O. Siniaguine and M. Hammond, Atmospheric Pressure Downstream Plasma-A New Tool for Semiconductor Processing, Solid State Technology, June, 1998. High speed scanning and intense heat removal make it difficult to achieve reliability in such systems.

U.S. Pat. No. 5,198,634 describes a plasma reactor for the removal of contamination using a much lower ratio of power density to gas pressure.

However, that system is not capable of the high rate etching needed under the temperature conditions which are required.

### OBJECTS AND SUMMARY OF THE INVENTION

It is in general an object of the invention to provide a new and improved etching system and process.

Another object of the invention is to provide a system and process of the above character Which are particularly suitable for use in the etching of organic materials.

These and other objects are achieved in accordance with the invention by providing a plasma reactor and process for very fast etching of organic materials in which a workpiece is placed on a pedestal in a chamber, gas is exhausted from the chamber, an oxidizing gas is introduced into the chamber through a showerhead electrode which is spaced from the pedestal by a distance on the order of 1.0 to 1.5 cm, RF power is applied to the pedestal and/or the showerhead electrode, and pressure within the chamber is maintained at a level on the order of 3 to 15 Torr while an organic material is removed from the workpiece.

### BRIEF DESCRIPTION OF THE DRAWINGS

The single FIGURE of drawing is side elevational view, somewhat schematic, of one embodiment of an etching system incorporating the invention.

### DETAILED DESCRIPTION

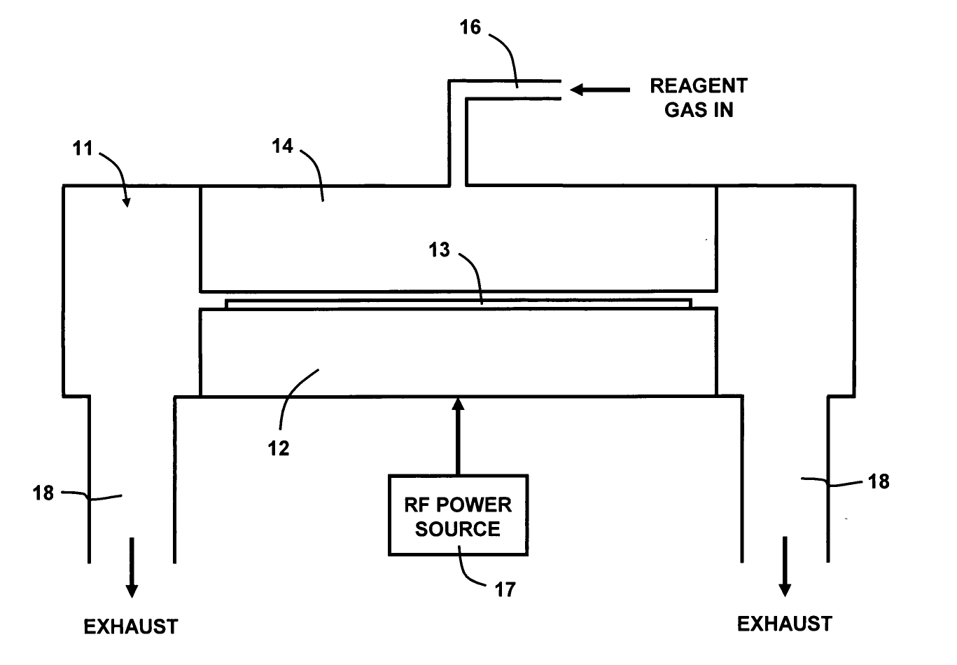

As illustrated in FIG. 1, the etching system includes a chamber 11 which contains a pedestal 12 on which a wafer 13 is placed. A showerhead electrode 14 is spaced above and parallel to the pedestal, and reagent gases are injected into the chamber through a gas line 16 connected to the showerhead electrode. An RF power source 17 supplies RF energy to the chamber to ionize the gas, and gas is pumped out of the chamber through exhaust ports 18.

Silicon Etching Process

The basic silicon etching process is done between electrodes which are spaced about 3 mm to 6 mm apart so as to concentrate the power on a small volume of gas. This makes the plasma density elevated and increases the etching rate. Reducing the gap between electrodes to this distance results in a stable and uniform electrical discharge between the electrodes at the desired process pressure with the desired process gas(es). When larger gaps were tried the plasma was not stable and caused uneven etching and unpredictable etching patterns on the silicon. This was found to be the case up to power densities of greater than 10 watts per square centimeter of electrode area.

The preferred gas mixture used for this process is a combination of sulfur hexafluoride and oxygen. Both of these gases are inexpensive and the mixture provided a great deal of fluorine atoms in the electrical discharge for the etching process to proceed at high rate. Nitrogen trifluoride was also tried but was found to cause degradation of surfaces in the reactor and not to give any higher etching rate than sulfur hexafluoride. It is not any better in this process as a source of fluorine and is enormously more expensive. Other oxidizing gases such as Nitrous oxide may also be used in the process but cause the cost of the process to increase. Since large flows of these gases need to be used to provide for such high etching rates the cost of the gas is a significant factor in the cost of the process and inexpensive gases are essential for the commercial competitiveness of the processes. Typical flows of such gases required for the etching process range from a few hundred standard cubic centimeters per minute (sccm) to as much as three thousand sccm, both forthe sulfur hexafluoride and for the oxygen or oxidizer. Other gases may be added to the process to slow the rate such as inert gases or methane or other hydrocarbon gases.

The preferred pressure for the silicon etching process is between 1.5 Torr and 10 Torr. The reason for the pressure having to be as high as this is to greatly reduce the energy of the ions which strike the substrate. High ion energy causes the sputtering of some of the exposed materials on the substrate such as metals, and can cause dislocations to be formed in the silicon crystal which degrade semiconductor function. Increasing the pressure increases the collisions that the ions make in the sheath regions of the plasma where the ions are accelerated by the potential difference between the electrode surface and the plasma. This potential difference can often be more than one hundred Volts or more and only if the ions make a number of collisions while being accelerated across this potential do they have energies which at a maximum are less than 20 eV per atom which is necessary to avoid sputtering. Higher pressures cause there to be more collisions of ions in the sheath which reduce ion energies. For silicon dislocations to be avoided when processing single crystal silicon wafers the energies of the ions which strike the surface should be less than or about 50 eV . At pressures less than 1.5 Torr the ion energies are likely to exceed this threshold for the type of plasma discharge needed to produce the high etching rates.

The preferred mode for the radio frequency power to be applied is by pulsing it with a duty cycle between 20% and about 60%. This reduces the heating of the substrate because the power of the plasma is only on the substrate during the on phase of the cycle. Some of these processes require that the wafer be kept below a certain temperature, that temperature usually being below 100° Celsius. However, the RF power density to plasma must be above a certain level in order to provide a stable discharge. Thus, the heating of the substrate may be reduced by pulsing the RF power, while not compromising the stability of the discharge or the uniformity of the etching.

The ratio of the RF power density (applied to the plasma while it is in the on phase of the duty cycle) to the total gas pressure needs to be at least 1.0 Watts per centimeter cubed per Torr of gas pressure. This is because below this level neither can the required etching rate be achieved, nor the plasma be made to operate in a stable way with the gas composition and pressure required for the high etching rate. Typically, above 25 Watts per centimeter cubed per Torr the heating of the substrate is unacceptably high. With a power density per pressure of between three and six Watts per centimeter cubed per Torr etching rates for the silicon of about seven to ten microns per minute are achieved.

Organic Etching Process.

With organic materials, the etching is done between electrodes which are spaced, or separated, by a distance on the order of about 1.0 cm to about 1.5 cm, with gas pressures on the order of about 3 Torr to about 15 Torr, and power density to gas pressure ratios ranging from about 0.2 watt/cm³/Torr to about 1.5 watt/cm³/Torr. The gas flow is preferably on the order of about 5 sccm/cm² to as much as 20 sccm/cm² of workpiece area. The substrate temperature is typically between about 150° and 300° Celsius. The RF power can be anywhere in the relatively wide range of about 25 KHz to about 27.12 MHz and can be pulsed, if desired. If pulsing is employed, the duty cycle should be at least 25%.

The preferred gas mixture used for this process is a combination of oxygen (or a strong oxidizer such as nitrous oxide) and a small percentage of sulfur hexafluoride or fluorocarbon gas. All of these gases, except nitrous oxide, are inexpensive and the mixture provides a great deal of oxygen atoms in the electrical discharge for the etching process to proceed at high rate. Since large gas flow is required for high etching rates, the cost of the gas is a significant factor in the cost of the process, and the less expensive gases are therefore generally preferred from a commercial standpoint. Such gas flows typically range from a few hundred standard cubic centimeters per minute (sccm) to as much as a few thousand sccm, both for the sulfur hexafluoride and for the oxygen or oxidizer. Other gases such as inert gases or methane or other hydrocarbon gases may be added to the process to slow the rate.

The relatively high gas pressures used in this process (3.0-15 Torr) are important in reducing the energy of the ions which strike the substrate. High ion energy causes the sputtering of exposed materials such as metals on the substrate. Increasing the pressure increases the collisions between the ions in the sheath regions of the plasma where the ions are accelerated by the potential difference between the electrode surface and the plasma. This potential difference can be a hundred volts or more, and by ensuring that the ions make a number of collisions while being accelerated across this potential, the energy of the ions can be reduced to a maximum of 20 eV per atom which is necessary to avoid sputtering.

This process is particularly suitable for use in the isotropic (non-directional) etching of photoresist, one example of which is stripping photoresist from very large rectangular substrates of glass or other materials used in the manufacture of large display screens such as thin film transistor/liquid crystal displays (TFT/LCD). In addition to being isotropic, the process is advantageous in that it has very low ion bombardment and does not sputter or otherwise damage the surface of the workpiece that is being etched.

It is apparent from the foregoing that a new and improved etching system and process have been provided. While only certain presently preferred embodiments have been described in detail, as will be apparent to those familiar with the art, certain changes and modifications can be made without departing from the scope of the invention as defined by the following claims.

1. A process for the fast etching of an organic material, comprising the steps of:
placing a workpiece on a pedestal in a chamber;
exhausting gas from the chamber;
introducing an oxidizing gas into the chamber through a showerhead electrode which is spaced from the pedestal by a distance on the order of 1.0 to 1.5 cm;
applying RF power to the pedestal and/or the showerhead electrode; and
maintaining pressure within the chamber at a level on the order of 3 to 15 Torr while an organic material is removed from the workpiece.

2. The process of claim 1 wherein the oxidizing gas contains oxygen or a strong oxidizer and a smaller percentage of a gas selected from the group consisting of sulfur hexafluoride, a fluorocarbon, and combinations thereof.

3. The process of claim 1 wherein an RF power density to gas pressure ratio on the order of 0.2 to 1.5 watt/cm³/Torr is maintained between the showerhead electrode and the pedestal.

4. The process of claim 1 wherein the gas is introduced into the chamber at a rate on the order of 5 to 20 sccm/cm² of workpiece area.

5. The process of claim 1 wherein the workpiece is at a temperature on the order of 150° to 300° Celsius.

6. The process of claim 1 wherein the RF power has a frequency within a range of about 25 KHz to about 27.12 MHz.

7. The process of claim 1 wherein the RF power is pulsed with a duty cycle greater than 25%.

8. A process for isotropically removing photoresist from a large rectangular substrate of glass or the like in the manufacture of a thin film transistor liquid crystal display (TFT/LCD), comprising the steps of:
placing the substrate on a pedestal in a chamber;
exhausting gas from the chamber;
introducing an oxidizing gas into the chamber through a showerhead electrode which is spaced from the pedestal by a distance on the order of 1.0 to 1.5 cm;
applying RF power to the pedestal and/or the showerhead electrode; and
maintaining pressure within the chamber at a level on the order of 3 to 15 Torr while the photoresist is isotropically etched from the substrate.

9. The process of claim 8 wherein the oxidizing gas contains oxygen or a strong oxidizer and a smaller percentage of a gas selected from the group consisting of sulfur hexafluoride, a fluorocarbon, and combinations thereof.

10. The process of claim 8 wherein an RF power density to gas pressure ratio on the order of 0.2 to 1.5 watt/cm³/Torr is maintained between the showerhead electrode and the pedestal.

11. The process of claim 8 wherein the gas is introduced into the chamber at a rate on the order of 5 to 20 sccm/cm² of substrate area.

12. The process of claim 8 wherein the substrate is at a temperature on the order of 150° to 300° Celsius.

13. The process of claim 1 wherein the RF power has a frequency within a range of about 25 KHz to about 27.12 MHz.

14. The process of claim 1 wherein the RF power is pulsed with a duty cycle greater than 25%.

15. A plasma reactor system for very fast etching of organic materials, comprising:
a chamber;
a pedestal for holding a workpiece within the chamber;
means for exhausting gas from the chamber;
a showerhead electrode positioned which is spaced above the pedestal by a distance on the order of 1.0 to 1.5 cm for injecting gas into the region between the pedestal and the showerhead;
means for introducing an oxidizing gas into the chamber through the showerhead electrode;
an RF power source connected to the pedestal and/or to the showerhead electrode; and
means for maintaining pressure within the chamber at a level on the order of 3 to 15 Torr.

16. The system of claim 15 wherein the oxidizing gas contains oxygen or a strong oxidizer and a smaller percentage of a gas selected from the group consisting of sulfur hexafluoride, a fluorocarbon, and combinations thereof.

17. The system of claim 15 including means for maintaining an RF power density to gas pressure ratio on the order of 0.2 to 1.5 watt/cm³/Torr between the showerhead electrode and the pedestal.

18. The system of claim 15 including means for introducing the gas into the chamber at a rate on the order of 5 to 20 sccm/cm² of workpiece area.

19. The system of claim 15 including means for maintaining the workpiece at a temperature on the order of 150° to 300° Celsius.

20. The system of claim 15 wherein the RF power has a frequency within a range of about 25 KHz to about 27.12 MHz.

21. The system of claim 15 including means for pulsing the RF power with a duty cycle greater than 25%.
